(19) United States
(12) Patent Application Publication
(10) Pub. No.: US 2026/0123292 A1
(43) Pub. Date: Apr. 30, 2026

(54) Nonvolatile Memory Devices Based on Hybrid Magnetic-Superconductor Soliton States

(71) Applicant: The United States of America, as represented by the Secretary of the Navy, Arlington, VA (US)

(72) Inventor: Sergio A. Montoya, Chula Vista, CA (US)

(21) Appl. No.: 18/930,799

(22) Filed: Oct. 29, 2024

(51) Int. Cl. H10N 60/20; G11C 11/44; H10B 99/00; H10N 60/85

(52) U.S. Cl. CPC H10N 60/208; G11C 11/44; H10B 99/10; H10N 60/85

(57) ABSTRACT

A cryogenic memory device comprising: a magnetic element made of thin film material and capable of forming at least one skyrmion; a superconducting element made of thin film material and capable of forming at least one superconducting vortex; and a nonmagnetic thin film barrier material that separates at top surface of magnetic element from a bottom surface of the superconducting element so as to form a skyrmion-based nonvolatile cryogenic memory.

### FEDERALLY-SPONSORED RESEARCH AND DEVELOPMENT

The United States Government has ownership rights in the invention claimed herein. Licensing and technical inquiries may be directed to the Office of Research and Technical Applications, Naval Information Warfare Center Pacific, Code 72120, San Diego, CA, 92152; voice (619) 553-5118; NIWC_Pacific_T2@us.navy.mil. Reference Navy Case Number 113237.

### BACKGROUND OF THE INVENTION

Superconductor-based quantum information and sensor technologies are a subject of intense research because they present a pathway to develop a new generation of high-performance technologies that consume less power and occupy a reduced footprint compared to the present state-of-the-art. There is a need for an improved cryogenic memory and storage device.

### SUMMARY

Disclosed herein is an embodiment of a cryogenic memory device comprising: a magnetic element, a superconducting element, and a nonmagnetic thin film barrier material. The magnetic element is made of thin film material and is capable of forming at least one skyrmion. The superconducting element is made of thin film material and is capable of forming at least one superconducting vortex. The nonmagnetic thin film barrier material separates a top surface of magnetic element from a bottom surface of the superconducting element so as to form a skyrmion-based nonvolatile cryogenic memory.

A nonvolatile, solid-state embodiment of a cryogenic memory device is also disclosed herein as comprising a plurality of memory cells and a processor. The plurality of memory cells is arranged in a cross-point architecture. Each memory cell comprises a magnetic element separated from a superconductor element by a nonmagnetic element. The processor is configured to encode binary information in the plurality of memory cells by injecting electrical current to stabilize a skyrmion state in each of the magnetic elements of selected memory cells thereby inducing creation of an Abrikosov vortex in the superconducting element of each of the selected memory cells.

Also disclosed herein is a method for providing random access memory comprising the following steps. The first step includes providing a plurality of memory cells where each cell has a bottom electrode mounted to a bottom surface of a magnetic element that has a top surface, which is separated from a superconducting element by a non-magnetic element. Another step provides for arranging the plurality of memory cells in a cross-point architecture. Another step provides for encoding binary information in the plurality of memory cells by injecting a first electrical current having a first polarity, a first pulse width, and a first pulse amplitude through a given bottom electrode to stabilize a skyrmion state in a corresponding magnetic element of a selected memory cell that corresponds to the given electrode thereby inducing creation of an Abrikosov vortex in a superconducting element corresponding to the selected memory cell.

### BRIEF DESCRIPTION OF THE DRAWINGS

Throughout the several views, like elements are referenced using like references. The elements in the figures are not drawn to scale and some dimensions are exaggerated for clarity.

FIG. 1A is a cross-sectional, side-view illustration of an embodiment of a cryogenic memory device.

FIG. 1B is a cross-sectional, top-view illustration of the cryogenic memory device 10 shown in FIG. 1A.

FIG. 1C is a cross-sectional, top-view illustration of the cryogenic memory device 10 shown in FIG. 1A.

FIG. 2 is a flowchart.

FIG. 3A is a cross-sectional side view illustration of an embodiment of a cryogenic memory device.

FIG. 3B is a cross-sectional top view illustration of an embodiment of a cryogenic memory device.

FIG. 3C is a cross-sectional top view illustration of an embodiment of a cryogenic memory device.

FIG. 3D is a cross-sectional side view illustration of an embodiment of a cryogenic memory device.

FIG. 3E is a cross-sectional top view illustration of an embodiment of a cryogenic memory device.

FIG. 3F is a cross-sectional top view illustration of an embodiment of a cryogenic memory device.

FIG. 3G is a cross-sectional side view illustration of an embodiment of a cryogenic memory device.

FIG. 3B is a cross-sectional top view illustration of an embodiment of a cryogenic memory device.

FIG. 3H is a cross-sectional top view illustration of an embodiment of a cryogenic memory device.

FIG. 3I is a cross-sectional top view illustration of an embodiment of a cryogenic memory device.

FIGS. 4A and 4B depict a binary encoding scheme for an embodiment of a cryogenic memory device.

FIGS. 4C and 4D are side-view illustrations of embodiments of a cryogenic memory device.

FIGS. 5A-5F are side-view illustrations of embodiments of a cryogenic memory device.

### DETAILED DESCRIPTION OF EMBODIMENTS

The disclosed cryogenic memory devices and methods below may be described generally, as well as in terms of specific examples and/or specific embodiments. For instances where references are made to detailed examples and/or embodiments, it should be appreciated that any of the underlying principles described are not to be limited to a single embodiment, but may be expanded for use with any of the other methods and systems described herein as will be understood by one of ordinary skill in the art unless otherwise stated specifically.

References in the present disclosure to “one embodiment,” “an embodiment,” or any variation thereof, means that a particular element, feature, structure, or characteristic described in connection with the embodiments is included in at least one embodiment. The appearances of the phrases “in one embodiment,” “in some embodiments,” and “in other embodiments” in various places in the present disclosure are not necessarily all referring to the same embodiment or the same set of embodiments.

As used herein, the terms “comprises,” “comprising,” “includes,” “including,” “has,” “having,” or any variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or.

Additionally, use of words such as “the,” “a,” or “an” are employed to describe elements and components of the embodiments herein; this is done merely for grammatical reasons and to conform to idiomatic English. This detailed description should be read to include one or at least one, and the singular also includes the plural unless it is clearly indicated otherwise.

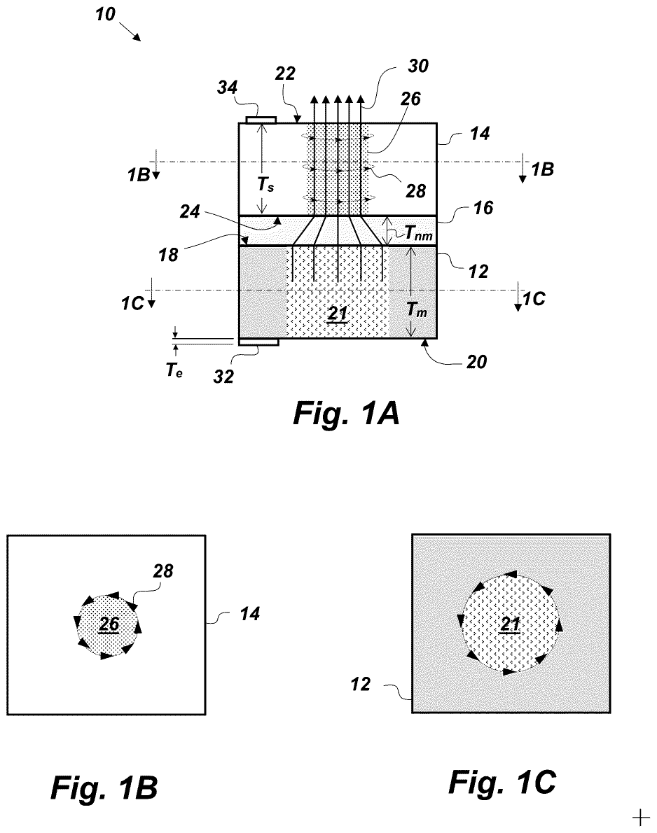

FIG. 1A is a cross-sectional, side-view illustration of an embodiment of a cryogenic memory device 10 that comprises, consists of, or consists essentially of a magnetic element 12, a superconducting element 14, and a nonmagnetic element 16. The cryogenic memory device 10 may be described as a nonvolatile solid-state memory device that exploits superconductor-magnetic soliton states (e.g., Abrikosov vortices and magnetic skyrmions) that can form in hybrid superconductor-magnet heterostructure materials. The magnetic element 12 has a top surface 18 and a bottom surface 20. The magnetic element 12 may be made of thin film material and is capable of forming at least one skyrmion 21, also referred to herein as a magnetic soliton (i.e., region with chiral spin texture), within the magnetic element 12. The superconducting element 14 has a top surface 22 and a bottom surface 24. When a skyrmion state is stabilized in the magnetic element 12, the dipolar fields (see dipole field lines 30) from the magnetic soliton can induce the formation of an Abrikosov soliton 26 (also referred to a superconducting vortex or vortex of supercurrents) in the superconducting element 14. The coupling between these distinct soliton states can be tuned by varying the thickness Tₙₘ of the nonmagnetic element 16 that separates the superconductor 14 and the magnetic element 12. By varying the thickness Tₙₘ of the nonmagnetic element 16, one can directly tune the dipole fields observed by the superconductor element 14, which can impact the size of the Abrikosov soliton 26.

FIG. 1B is a cross-sectional, top-view illustration of the cryogenic memory device 10 shown in FIG. 1A. The superconducting element 14 may be made of thin film material and is capable of forming at least one superconducting vortex 26, also referred to herein as an Abrikosov vortex, or superconducting soliton. The nonmagnetic element 16 may be a nonmagnetic thin film barrier material that separates the top surface 18 of the magnetic element 12 from the bottom surface 22 of the superconducting element 14 so as to form a skyrmion-based nonvolatile cryogenic memory. In FIG. 1B, supercurrent lines 28 may be seen circling the superconducting vortex 26. The size of the superconductor and magnetic soliton states (i.e., the superconducting vortex 26 and the skyrmion 21) can be designed by carefully engineering the material and thickness Tₛ of the superconductor 16 and the materials properties and the thickness Tₘ of the magnetic element 12. Thus, the size of each soliton state, the temperature at which these states are formed, and the volume of each memory cell can be controlled.

FIG. 1C is a cross-sectional, top-view illustration of the cryogenic memory device 10 shown in FIG. 1A. FIG. 1C shows the skyrmion 21, or region with chiral spin texture, within the magnetic element 12. Referring back to FIG. 1A, dipole field lines 30 are also illustrated. The skyrmion-based nonvolatile cryogenic memory may be configured such that when an electrical current having a first polarity, a first pulse width, and a first pulse amplitude is provided through a first electrode 32 disposed on a bottom surface 20 of the magnetic element 12, at least one skyrmion 21 is generated in the magnetic element 12. As shown, the skyrmion 21 in the magnetic element 12 induces the formation of at least one superconducting vortex 26 in the superconducting element 14 such that data may be written to the cryogenic memory device 10.

The cryogenic memory device 10 may be utilized as a building block to realize cryogenic memory and data storage capabilities for superconducting computing and/or sensor systems. Binary information may be encoded in the superconductor-magnetic states that can form in a hybrid superconductor-magnetic structure such as shown in FIGS. 1A-1C. The cryogenic memory device 10 may comprise multiple memory cells arranged in a cross-point racetrack memory architecture where electrical currents may be utilized to deterministically modify (e.g., write) the superconductor-magnetic states in the hybrid structure. Alternatively, the cryogenic memory device 10 may comprise a plurality of individual memory cells in a neuromorphic memory architecture. Electrical currents may also be used to read the superconductor-magnetic state encoded in the hybrid structure. The cryogenic memory device 10 provides a pathway to integrate low-power, high-scalable, high-endurance, fast-read and fast-write cryogenic memory and storage into superconducting computing and/or sensor systems. An electrical current may be utilized to induce and annihilate the formation of the magnetic skyrmion 21 in the magnetic element 12. Reading the binary information in an individual memory cell can be performed either through the corresponding superconductor element 14 or the magnetic element 12, depending where information will be transmitted. For example, if only two electrodes are used to interface with the cryogenic memory device 10 (e.g., top and bottom electrodes 34 and 32), then reading the magnetoresistance of the device can only be performed across the device.

Now, if we consider an embodiment of the cryogenic memory device 10 that exhibits four terminals/electrodes (two at the bottom and two at the top), then it is possible to independently read the resistance of the superconducting and magnetic element 14 and 12. The latter facilitates using different test (read) currents with different attributes (e.g., lower current density) to measure the presence/absence of either a skyrmion or Abrikosov vortex state. This device architecture enables modalities for hybrid computing that interface superconducting and CMOS electronics to the same memory storage without incurring the up/down-conversion that is required to move information from superconducting to CMOS electronics, and vice-versa. A similar argument could be realized for a three-terminal embodiment of the cryogenic memory device 10 (e.g., two electrodes on the bottom and one on the top, or vice-versa depending on the application). If computations are performed in superconducting electronics, then the cryogenic memory device 10 would likely require two electrodes on the superconducting element 10 and one on the magnetic element 12. An analogous argument can be made if data processing is performed in CMOS electronics with electrodes reversed.

The cryogenic memory device 10 may be used to delete data from a given memory cell by providing a second electrical current with a second polarity, a second pulse width, or a second pulse amplitude that respectively differ from the first polarity, the first pulse width, or the first pulse amplitude through the first electrode 32 such that at least one skyrmion 21 associated with the given memory cell is annihilated. That in turn causes the associated superconducting vortex 26 to be annihilated such that the data may be deleted from the given memory cell. In other words, one may delete binary information from the given memory cell by injecting a second electrical current through the bottom electrode associated with the given memory cell such that the skyrmion state in the given memory cell is annihilated, which in turn causes the Abrikosov vortex in the corresponding superconducting element to be annihilated. One may infer a total number of skyrmions 21 and superconducting vortices 26 by passing a test (read) current through the first electrode 32 to a second electrode 34 disposed on the top surface 22 of the superconducting element 14. The test (read) current may be used to determine a magnetoresistance of the cryogenic memory device 10 thereby enabling read operations. A magnetoresistance value equal to or above a threshold value may represent a “1” and a magnetoresistance value below the threshold value may represent a “0”.

Suitable examples of material from which the magnetic element 12 may be made, include, but are not limited to a ferromagnetic layer or alloy comprising at least one material selected from the group consisting of Fe, Co, Ni, a simple or double ferromagnetic perovskite, a Heusler alloy, and a magnetic semiconductor. The ferromagnetic layer or alloy may be interfaced with a nonmagnetic layer. In one embodiment of the cryogenic memory device 10, the magnetic element 12 may have a thickness Tₘ of approximately 1 nanometer (nm) to 100 nm. The magnetic element 12 may be made of single, or multi-element material (e.g., individual layers or alloy). The nonmagnetic element 16 may be a thin normal metal (i.e., a metal that is not superconducting) that enables field-induced coupling between the magnetic and superconductor soliton states. A suitable example of the superconducting element 14 is, but is not limited to, a type II superconductor selected from one or more of Nb, YBCO, NbTi, NbN, NbGe, NbAl, NbCN, and NbSn. In some embodiments of the cryogenic memory device 10, the thickness Tₛ of the superconducting element 14 may be approximately 1 nm to 100 nm. The superconducting element 14 may be a thin-film or thin-film heterostructure. The superconducting element 14 may be made of a single or multi-element material (e.g., individual layers or alloy).

The first electrode 32 may be made of a nonmagnetic material, suitable examples of which include, but are not limited to, one or more of the following elements Cu, Mo, Rh, Pd, Ta, W, Re, Os, Ir, Pt, Au, Pb, and Bi. In addition, the first electrode 32 may be doped with an element of the 3d, 4d, 5d, or 5f periodic groups. The first electrode 32 may have a thickness Tₑ that is approximately 1 nm to 20 nm.

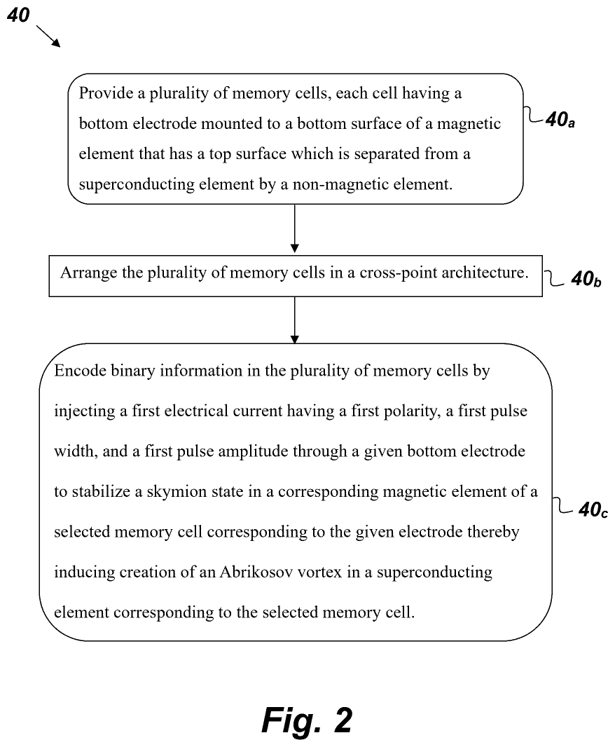

FIG. 2 is a flowchart of a method 40 for providing random access memory comprising the following steps. The first step 40a involves providing a plurality of memory cells, each cell having a bottom electrode mounted to a bottom surface of a magnetic element that has a top surface that is separated from a superconducting element by a non-magnetic element. Another step 40b provides for arranging the plurality of memory cells in a cross-point architecture. Another step 40c provides for encoding binary information in the plurality of memory cells by injecting a first electrical current having a first polarity, a first pulse width, and a first pulse amplitude through a given bottom electrode to stabilize a skyrmion state in a corresponding magnetic element of a selected memory cell corresponding to the given electrode thereby inducing creation of an Abrikosov vortex in a superconducting element corresponding to the selected memory cell.

Method 40 may further comprise reading from the random access memory by passing a test (read) current through the given bottom electrode to a top electrode (e.g., electrode 34) disposed on the top surface of the corresponding superconducting element 14 (such as shown in FIG. 1) to determine a magnetoresistance of the selected memory cell, from which a total number of skyrmions and superconducting vortices in the selected memory cell may be inferred, wherein a magnetoresistance value equal to or above a threshold value represents a “1” and magnetoresistance value below the threshold value represents a “0”.

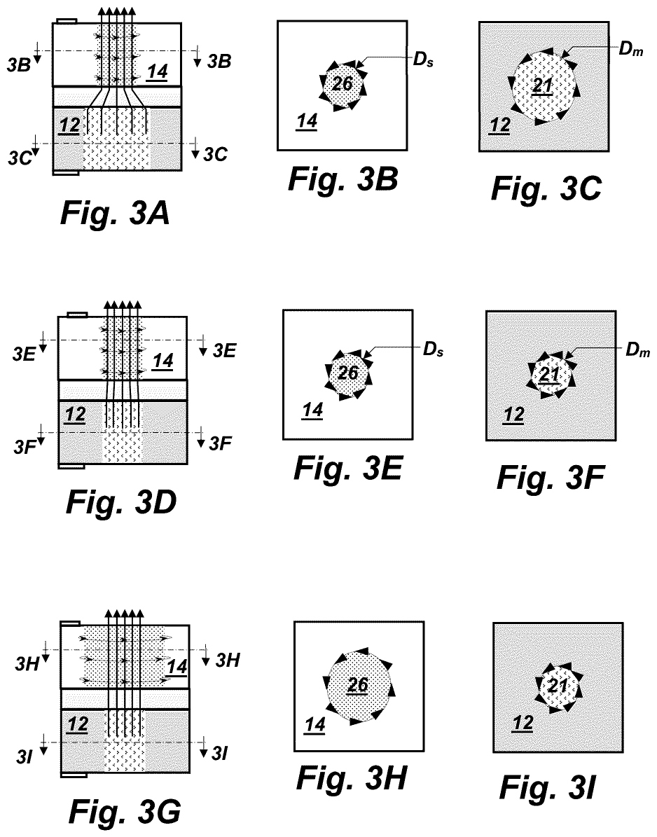

FIGS. 3A through 3I are illustrations of different embodiments of the cryogenic memory device 10, highlighting potential hybrid soliton state pairs that could be formed in these embodiments. FIGS. 3A, 3D, and 3G are cross-sectional side view illustrations of three different embodiments of the cryogenic memory device 10. FIGS. 3B, 3C, 3E, 3F, 3H, and 3I are cross-sectional top view illustrations of three different embodiments of the cryogenic memory device 10. FIGS. 3A, 3B, and 3C show an embodiment of the cryogenic memory device 10 where the Abrikosov vortex 26 has a diameter Dy that is smaller than a diameter Dm of the skyrmion 21. FIGS. 3D, 3E, and 3F show an embodiment of the cryogenic memory device 10 where the Abrikosov vortex 26 has a diameter Dy that is equal to the diameter Dm of the skyrmion 21. FIGS. 3G, 3H, and 3I show an embodiment of the cryogenic memory device 10 where the Abrikosov vortex 26 has a diameter Dy that greater than the diameter Dm of the skyrmion 21. The formation of a magnetic skyrmion 21 in the magnetic element 12 may result from the injection of an electrical current pulse(s) that can flow parallel or transverse to the magnetic element layer 12. Depending on the physical phenomena exploited (e.g., Joule heating, spin-transfer torque, spin-orbit torque, spin-polarized supercurrents, etc.), the architecture of the cryogenic memory device 10 and material properties of the superconducting element 14, the magnetic element 12, and the nonmagnetic element 16 can be tailored to obtain high efficiency write and delete operation. The ability to adjust properties of the magnetic element 12 (e.g., uniaxial anisotropy, magnetization, Dzyaloshinskii Moriya exchange, Heisenberg exchange, and damping) provides a pathway to design embodiments of the cryogenic memory device 10 that can operate with different high and low temperature superconductor materials (e.g., YBCO, or Nb).

The order of the superconductor and magnetic elements 14 and 12, can be reversed. In other words, the magnetic element 12 can be on top of the nonmagnetic element 16 and the superconducting element 14. Given the proximity effect (i.e., when a superconductor material is interfaced with a normal metal (i.e., non-superconducting), the interface of the superconductor material becomes non-superconducting below the critical temperature). There may be embodiments of the cryogenic memory device 10 that take advantage of the proximity effect that do not include the nonmagnetic element 16. Higher complexity encoding schemes could be utilized to represent binary information.

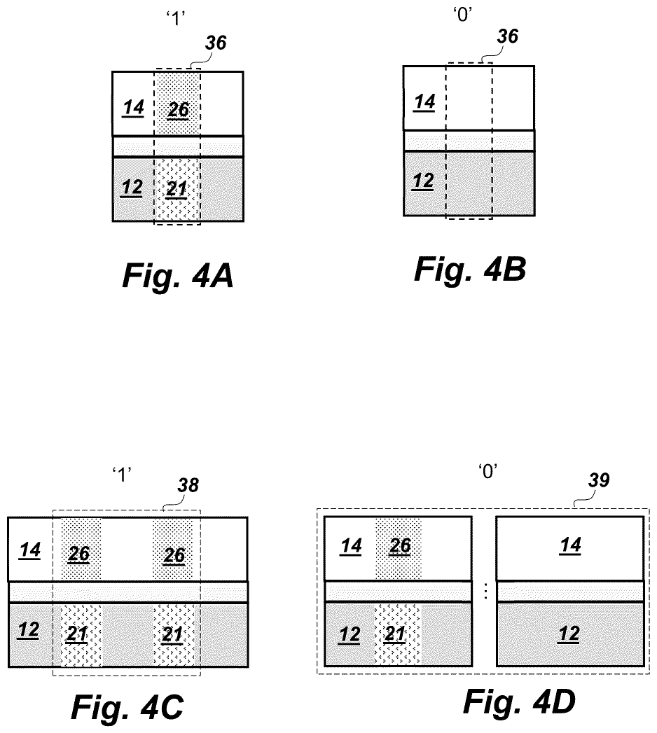

FIGS. 4A and 4B depict a binary encoding scheme for an embodiment of the cryogenic memory device 10 where rectangle 36 surrounds a location that can support a single hybrid soliton pair (i.e., one superconducting vortex 26 and one skyrmion 21) that represents a bit of data. The presence or absence of the hybrid soliton pair can represent either a ‘1’, or a ‘0’ of binary data as desired. In this example, the presence of the hybrid soliton pair in rectangle 36 shown in FIG. 4A is used to represent a ‘1’ and the absence of the soliton pair in rectangle 36 shown in FIG. 4B represents a ‘0’.

FIGS. 4C and 4D are side-view illustrations of embodiments of the cryogenic memory device 10 with higher complexity binary encoding where the rectangle 38 surrounds a location that can support two hybrid soliton pairs that together represent a single bit of data. In other words, the presence or absence of the two hybrid soliton pairs can represent either a ‘1’, or a ‘0’ of binary data as desired. In this example (i.e., the one shown in FIG. 4C), the presence of the two hybrid soliton pairs in rectangle 38 are used to represent a ‘1’ and the absence of the both soliton pairs in rectangle 39 shown in FIG. 4D represents a ‘0’. Alternative permutations from the latter are possible.

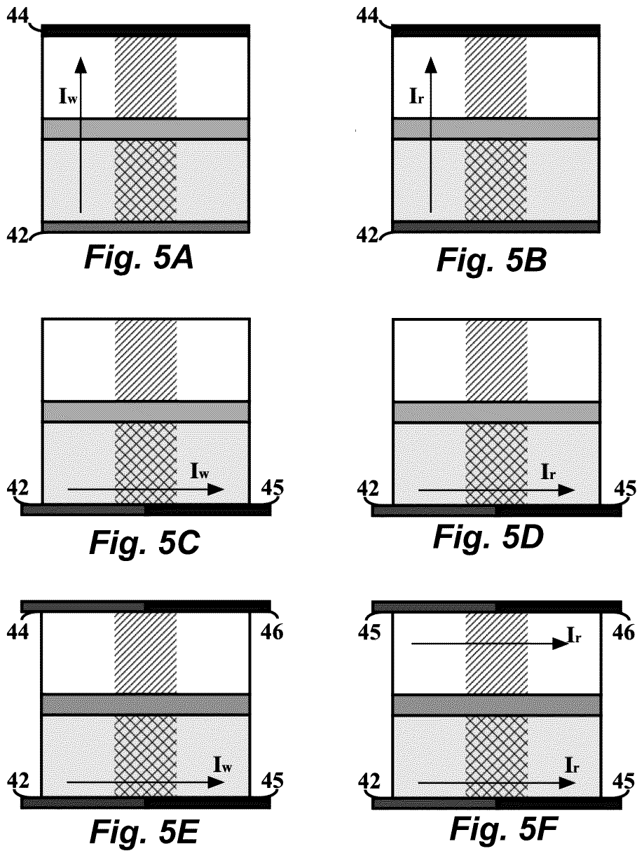

FIGS. 5A-5F are side-view illustrations of embodiments of the cryogenic memory device 10 with different electrode architectures to facilitate write/read operations. FIGS. 5A-5B depict a two terminal architecture cryogenic memory device 10 with a bottom electrode 42 on the bottom surface of the magnetic element 12 and a top electrode 44 on the top surface of the superconducting element 14. FIG. 5A depicts an electrical current pulse I_{w} being passed between a bottom electrode 42 and a top electrode 44 across an embodiment of the cryogenic memory device 10 to “write” a skyrmion 21 in the magnetic element 12. FIG. 5B depicts an electrical test (read) current Ir being passed between the bottom electrode 42 and the top electrode 44 across an embodiment of the cryogenic memory device 10 to determine the presence/absence of a skyrmion 21 and Abrikosov vortex 26. FIG. 5C-5D depict a two terminal architecture cryogenic memory device 10 with two bottom electrodes 42 and 45 on the bottom surface of the magnetic element 12. FIG. 5C depicts an electrical current pulse I_{w} being passed between a bottom electrode 42 and a bottom electrode 45 along a bottom surface of the magnetic element 12 to “write” a skyrmion 21 in the magnetic element 12. FIG. 5D depicts an electrical test (read) current pulse Ir being passed between a bottom electrode 42 and a bottom electrode 45 along a bottom surface of the magnetic element 12 to “read” a skyrmion 21 in the magnetic element 12. FIG. 5E-5F depict a four-terminal architecture cryogenic memory device 10 with two electrodes 42 and 45 on the bottom surface of the magnetic element 12 and two electrodes 44 and 46 on the top surface of the superconducting element 14. FIG. 5E depicts an electrical current pulse I_{w} being passed between a bottom electrode 42 and a bottom electrode 45 along the bottom surface of the magnetic element 12 to “write” a skyrmion 21 in the magnetic element 12. FIG. 5F depicts two possible read operations for the four-terminal architecture cryogenic memory device: passing an electrical test (read) current pulse Ir between a bottom electrode 42 and a bottom electrode 45 along a bottom surface of the magnetic element 12 enables reading the presence/absence of a skyrmion 21 in the magnetic element 12; meanwhile, passing an electrical test (read) current pulse Ir between a top electrode 44 and a top electrode 46 along a top surface of the superconducting element 14 enables reading the presence/absence of an Abrikosov vortex 26 in the superconducting element 14.

From the above description of the cryogenic memory device 10, it is manifested that various techniques may be used for implementing the concepts of the cryogenic memory device 10 without departing from the scope of the claims. The described embodiments are to be considered in all respects as illustrative and not restrictive. The method/apparatus disclosed herein may be practiced in the absence of any element that is not specifically claimed and/or disclosed herein. It should also be understood that the cryogenic memory device 10 is not limited to the particular embodiments described herein, but is capable of many embodiments without departing from the scope of the claims.

I claim:

1. A cryogenic memory device comprising:
a magnetic element made of thin film material and capable of forming at least one skyrmion;
a superconducting element made of thin film material and capable of forming at least one superconducting vortex; and
a nonmagnetic thin film barrier material that separates a top surface of magnetic element from a bottom surface of the superconducting element so as to form a skyrmion-based nonvolatile cryogenic memory.

2. The cryogenic memory device of claim 1, wherein the skyrmion-based nonvolatile cryogenic memory is configured such that when an electrical current having a first polarity, a first pulse width, and a first pulse amplitude is provided through a first electrode disposed on a bottom surface of the magnetic element at least one skyrmion is generated in the magnetic element, and wherein the at least one skyrmion in the magnetic element induces the formation of at least one superconducting vortex in the superconducting element such that data may be written to the skyrmion-based nonvolatile cryogenic memory.

3. The cryogenic memory device according to claim 2, wherein the skyrmion-based nonvolatile cryogenic memory is further configured such when an electrical current with a second polarity, a second pulse width, or a second pulse amplitude that respectively differ from the first polarity, the first pulse width, or the first pulse amplitude is provided through the first electrode, the at least one skyrmion is annihilated, which in turn causes the at least one superconducting vortex to be annihilated such that the data may be deleted from the skyrmion-based nonvolatile cryogenic memory.

4. The cryogenic memory device according to claim 3, wherein the skyrmion-based nonvolatile cryogenic memory is further configured such that a total number of skyrmions and superconducting vortices may be inferred by passing a test current through the first electrode to a second electrode disposed on the top surface of the superconducting element to determine a magnetoresistance of the cryogenic memory device thereby enabling read operations.

5. The cryogenic memory device according to claim 1, wherein the magnetic element comprises at least one ferromagnetic layer or alloy comprising at least one material selected from a group consisting of Fe, Co, Ni, a simple or double ferromagnetic perovskite, a Heusler alloy, and a magnetic semiconductor.

6. The cryogenic memory device according to claim 5, wherein the magnetic element thickness is approximately 1 nm to 100 nm.

7. The cryogenic memory device according to claim 6, wherein the superconductor element is a type II superconductor selected from one or more of Nb, YBCO, NbTi, NbN, NbGe, NbAl, NbCN, and NbSn.

8. The cryogenic memory device according to claim 7, wherein the superconducting element thickness is approximately 1 nm to 100 nm.

9. The cryogenic memory device according to claim 4, wherein the first electrode is made of a nonmagnetic layer or alloy comprising at least one material from among the elements: Cu, Mo, Rh, Pd, Ta, W, Re, Os, Ir, Pt, Au, Pb, and Bi.

10. The cryogenic memory device according to claim 9, wherein the first electrode thickness is approximately 1 nm to 20 nm.

11. The cryogenic memory device according to claim 1, wherein the skyrmion-based nonvolatile cryogenic memory comprises a plurality of individual memory cells in a cross-point architecture.

12. The cryogenic memory device according to claim 1, wherein the skyrmion-based nonvolatile cryogenic memory comprises a plurality of individual memory cells in a neuromorphic memory architecture.

13. A nonvolatile, solid-state memory comprising
a plurality of memory cells arranged in a cross-point architecture, each memory cell comprising a magnetic element separated from a superconductor element by a nonmagnetic element; and
a processor configured to encode binary information in the plurality of memory cells by injecting electrical current to stabilize a skyrmion state in each of the magnetic elements of selected memory cells thereby inducing creation of an Abrikosov vortex in the superconducting element of each of the selected memory cells.

14. The nonvolatile, solid-state memory of claim 13, wherein a thickness of the non-magnetic element of each memory cell is adjusted to a respective desired thickness so as to influence a size of a skyrmion-vortex pair created in each memory cell.

15. The nonvolatile, solid-state memory of claim 14, wherein the magnetic element and the superconducting element each have a thickness of approximately 1 nm to 100 nm.

16. A method for providing random access memory comprising:
providing a plurality of memory cells, each cell having a bottom electrode mounted to a bottom surface of a magnetic element that has a top surface which is separated from a superconducting element by a non-magnetic element;
arranging the plurality of memory cells in a cross-point architecture; and
encoding binary information in the plurality of memory cells by injecting a first electrical current pulse having a first polarity, a first pulse width, and a first pulse amplitude through a given bottom electrode to stabilize a skyrmion state in a corresponding magnetic element of a selected memory cell corresponding to the given electrode thereby inducing creation of an Abrikosov vortex in a superconducting element corresponding to the selected memory cell.

17. The method of claim 16, further comprising: deleting the binary information by injecting a second electrical current pulse through the given bottom electrode such that the skyrmion state is annihilated, which in turn causes the Abrikosov vortex in the corresponding superconducting element to be annihilated.

18. The method of claim 17, wherein the second electrical current pulse has a polarity, amplitude and width that differ from the first electrical current pulse.

19. The method of claim 17, further comprising: reading from the random access memory by passing a test current through the given bottom electrode to a top electrode disposed on the top surface of the corresponding superconducting element to determine a magnetoresistance of the selected memory cell, from which a total number of skyrmions and superconducting vortices in the selected memory cell may be inferred, wherein a magnetoresistance value equal to or above a threshold value represents a “1” and magnetoresistance value below the threshold value represents a “0”.

20. The method of claim 19, wherein the magnetic elements and the superconducting elements each have a thickness of approximately 1 nm to 100 nm.
